(19) United States
(12) Patent Application Publication
(10) Pub. No.: US 2008/0115821 A1
(43) Pub. Date: May 22, 2008

(54) MULTILAYER TRANSPARENT CONDUCTIVE OXIDE FOR IMPROVED CHEMICAL PROCESSING

(76) Inventors: Li Xu, Santa Clara, CA (US); Peter G. Borden, San Mateo, CA (US)

Correspondence Address: Patent Counsel, MS/2061;Legal Affairs Dept., Applied Materials, Inc., P.O. Box 450A, Santa Clara, CA, 95052, US

(21) Appl. No.: 11/562,565

(22) Filed: Nov. 22, 2006

(51) Int. Cl. H01L 31/042

(52) U.S. Cl. 136/244; 216/41

(57) ABSTRACT

A TCO layer structure and methods of processing the layer in thin film materials including other layers such as layers of CIGS material are disclosed herein. According to one aspect, the invention includes a novel design of a multi-layer TCO structure. According to another aspect, the TCO layer structure of the invention is comprised of inexpensive materials and is inexpensive to process and recycle. According to another aspect, the TCO layer structure of the invention is capable of being patterned using photolithographic and etch processing, but is also chemically durable.

### FIELD OF THE INVENTION

The present invention relates generally to patterning thin film materials, and more particularly to a method for improved chemical processing of thin films containing CIGS material and a transparent conductive oxide layer.

### BACKGROUND OF THE INVENTION

Thin film materials such as those comprising amorphous silicon, micro-crystalline silicon, Cu(In,Ga)Se, i.e. CIGS, and CdTe are attractive for use in such devices as thin film photovoltaic panels. In an example of prior art processes to fabricate devices comprising thin film materials, laser and mechanical scribes are commonly used to pattern the material layers. Such prior art patterning processes have a number of drawbacks. For example, they create wide scribes, defects, and shunt current paths. Furthermore, they provide limited means for wiring devices in series-parallel arrangements that might, in the case of photovoltaic modules, reduce sensitivity to shading losses or non-uniformity.

For these and other reasons, lithographic patterning processes have been considered in place of laser and mechanical scribes. Such processes could provide the ability to form more sophisticated interconnect patterns that can include features such as series-parallel wiring and pads for protect diodes and internal contacts. However, these processes would require the ability to etch the semiconducting or absorbing layer such as CIGS, and in some cases, to do so selectively to other material layers in the devices. Until recently, this was not known in the art. But co-pending application Ser. No. 11/395,080, filed Mar. 31, 2006 advanced the state of the art by providing an example etch process capable of etching CIGS, with consideration of selectivity to other material layers.

Meanwhile, certain thin film devices also include a transparent conducting oxide (TCO) layer. TCOs typically include semiconducting oxides of tin, indium, zinc, and cadmium, and the multi-component or doped oxides of these elements. As a consequence of their electrically conductive and optically transparent properties, TCOs are used as front-surface electrodes for solar cells and flat-panel displays, for example.

The ability to pattern devices including semiconducting or absorbing layers such as CIGS using etch and lithographic processes, which is made possible by the co-pending application, makes it desirable to similarly pattern devices further including a TCO layer. In particular, when TCO layers are included in or combined with thin film layers having CIGS material, regions of the TCO layers will also need to be removed. However, a problem arises that the TCO layer needs to remain chemically resistant or stable in the face of this and other chemical processing of the device. Another problem is that certain TCO materials are expensive.

For example, flat panel displays mainly use indium-tin-oxide (ITO) as their TCO layer material, while photovoltaics commonly use ZnO film. ITO contains about 90% of InO and 10% of SnO and, as indium is a very rare and expensive element, the cost of ITO is much higher than ZnO. Some would like to replace ITO with ZnO because of its lower cost. However, ZnO is difficult to use with conventional photolithography process that employ wet treatments, because doped ZnO films are more easily etched by both acid and alkaline solutions than ITO films. Accordingly, after ZnO film is deposited (and patterned) it cannot be exposed to other chemicals due to its poor chemical durability, and subsequent processing will result in damage to the TCO layer.

Therefore, there remains a need in the art for a TCO layer that is both inexpensive and chemically durable in photolithographic and etch processing.

### SUMMARY OF THE INVENTION

The present invention provides a TCO layer structure and methods of processing the layer in thin film materials including other layers such as layers of CIGS material. According to one aspect, the invention includes a novel design of a multi-layer TCO structure. According to another aspect, the TCO layer structure of the invention is comprised of inexpensive materials and is inexpensive to process and recycle. According to another aspect, the TCO layer structure of the invention is capable of being patterned using photolithographic and etch processing, but is also chemically durable.

In furtherance of these and other objects, a TCO structure according to the invention comprises a first TCO material and a second different TCO material that protects the first TCO material during chemical processing of a thin film device.

In additional furtherance of the above and other objects, a processing method according to the invention comprises forming a TCO structure comprised of at least two different TCO materials, including the TCO structure in a thin film stack, and using an etch process to completely etch through a portion of the thin film stack including the TCO structure, wherein the forming step includes selecting the TCO materials such that the structure is not degraded by the etch process.

### BRIEF DESCRIPTION OF THE DRAWINGS

These and other aspects and features of the present invention will become apparent to those ordinarily skilled in the art upon review of the following description of specific embodiments of the invention in conjunction with the accompanying figures, wherein:

FIGS. 1A-G show an example process flow for a photovoltaic module using an etch process wherein the module includes a TCO layer in accordance with an embodiment of the invention.

### DETAILED DESCRIPTION OF THE PREFERRED EMBODIMENTS

The present invention will now be described in detail with reference to the drawings, which are provided as illustrative examples of the invention so as to enable those skilled in the art to practice the invention. Notably, the figures and examples below are not meant to limit the scope of the present invention to a single embodiment, but other embodiments are possible by way of interchange of some or all of the described or illustrated elements. Moreover, where certain elements of the present invention can be partially or fully implemented using known components, only those portions of such known components that are necessary for an understanding of the present invention will be described, and detailed descriptions of other portions of such known components will be omitted so as not to obscure the invention. In the present specification, an embodiment showing a singular component should not be considered limiting; rather, the invention is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present invention encompasses present and future known equivalents to the known components referred to herein by way of illustration.

Generally, the present inventors have discovered a TCO layer structure that uses inexpensive materials but is chemically durable in the face of processing such as photolithographic and etch processes. Moreover, the TCO layer according to the invention has low toxicity.

Some TCO materials and the chemicals that are known to etch them are listed in TABLE 1 below. See generally, Roy G. Gordon, “Criteria for Choosing Transparent Conductors,” MRS Bulletin, Vol. 25(8), pp. 52-57 (2000); and T. Minami, “Transparent conducting oxide semiconductors for transparent electrodes,” Semiconductor Science and Technology, Vol 20, pp. S35-S44 (2005). The present inventors recognize that the TCO material zinc oxide is the easiest material to etch, tin oxide is the most difficult, and indium oxide is intermediate in etching difficulty. On the other hand, the ability of a TCO to withstand other chemicals is inversely related to its ease of etching. So, zinc oxide (ZnO) is readily attacked by acids or bases, while tin oxide (SnO₂) is the most resistant.

TABLE 1

| Material | Etchant |
|---|---|
| ZnO | Dilute acids |
| Zno | Ammonium chloride |
| In₂O₃ | HCl + HNO₃ or FeCl₃ |
| SnO₂ | Zn + HCl |
| SnO₂ | CrCl₂ |

In addition to chemical resistance, another factor to consider in selecting TCO materials is cost. The cost of producing a TCO depends on the cost of the raw materials and the cost of processing it into a thin layer. Between zinc, tin and indium, the raw material cost generally increases in this order: Zn<Sn<In. With respect to indium, it is a rare and expensive element that is obtained as a byproduct of the mining of ores for their content of other metals such as zinc and lead. Thus, even if it is desired to use indium, the supply of indium cannot be increased significantly without causing an increase in its price. Toxicity affects the cost of handling and processing TCO materials as well as costs for recycling at the end of the product's lifetime. Between zinc, tin and indium, toxicity generally increases in this order: Zn<Sn<In.

The present inventors therefore recognize that, between TCO materials comprised of zinc, tin and indium, ZnO has the lowest cost and toxicity, but lowest chemical durability; InO has the highest cost and toxicity and moderate chemical durability; and SnO has moderate cost and toxicity, and highest chemical durability.

According to certain aspects, therefore, the present invention relates to a multi-layer structure for a TCO. In one example, the TCO comprises a substantially large portion of (e.g. about 90%) of ZnO material and a relatively smaller portion (e.g. about 10%) of InO, SnO or ITO material. Accordingly, in an example application in a device having thin film materials, a TCO structure according to the invention has a ZnO layer about 4500 Å thick and an InO, SnO or ITO layer about 500 Å thick. The multi-layer structure can be formed, for example, by sequential deposition with sputtering or chemical vapor deposition tools. An example sputtering technique that can be adapted by those skilled in the art to form the TCO layer structure of the invention is described in X. W. Sun et al., “Improved ITO thin films with a thin ZnO buffer layer by sputtering,” Thin Solid Films, Vol. 360, pp. 75-81 (2000).

It should be noted that ZnO films are often doped with Al, B, etc. to improve their electrical and/or optical properties. Intrinsic (i.e. un-doped) ZnO, doped ZnO and combinations thereof are commonly used in thin film devices, and embodiments of the invention respectively include these alternatives. It should be further noted that terms “layer” or “multi-layer” as used to describe the TCO structure of the invention should be construed broadly, and should not be limited to any particular shape or composition.

By virtue of the multi-layer TCO structure of the invention, many advantages are obtained. For example, because inexpensive ZnO comprises the bulk of the structure, low cost is achieved. Normally, when ZnO is used by itself and exposed to chemicals such as silicon nitride and/or silicon oxide during an etch process, it is easily attacked by those chemicals. However, ITO and/or SnO has sufficient chemical endurance to these etchants. Accordingly, because ITO and/or SnO is further provided in the TCO as a protective layer, it can protect the ZnO film from adverse effects during etch processing, thereby providing chemical inertness to enable patterning. Therefore, low cost ZnO materials still comprise the bulk of the TCO layer, and the thin protective layer of ITO and/or SnO does not increase the cost substantially.

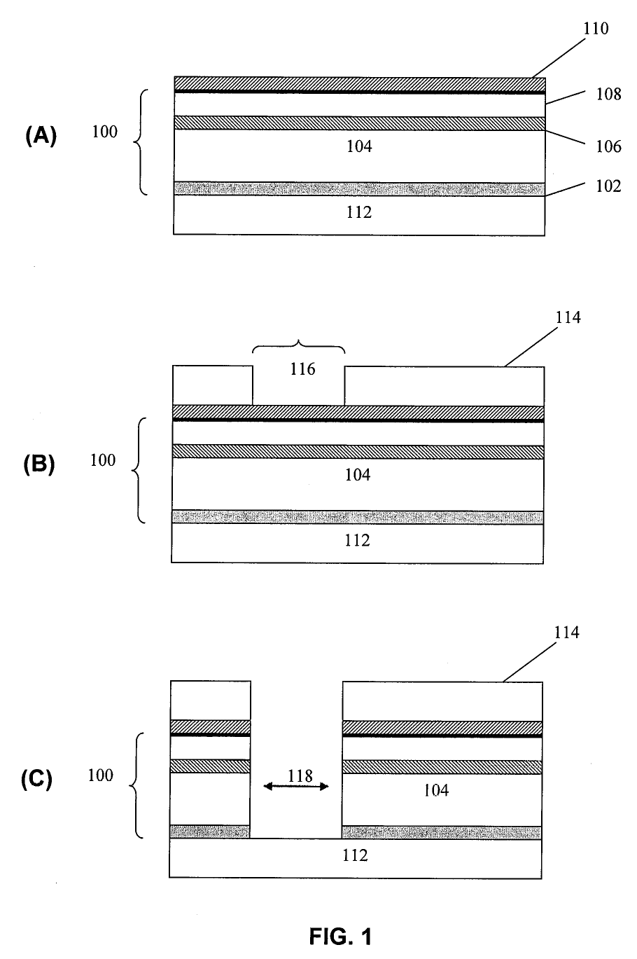

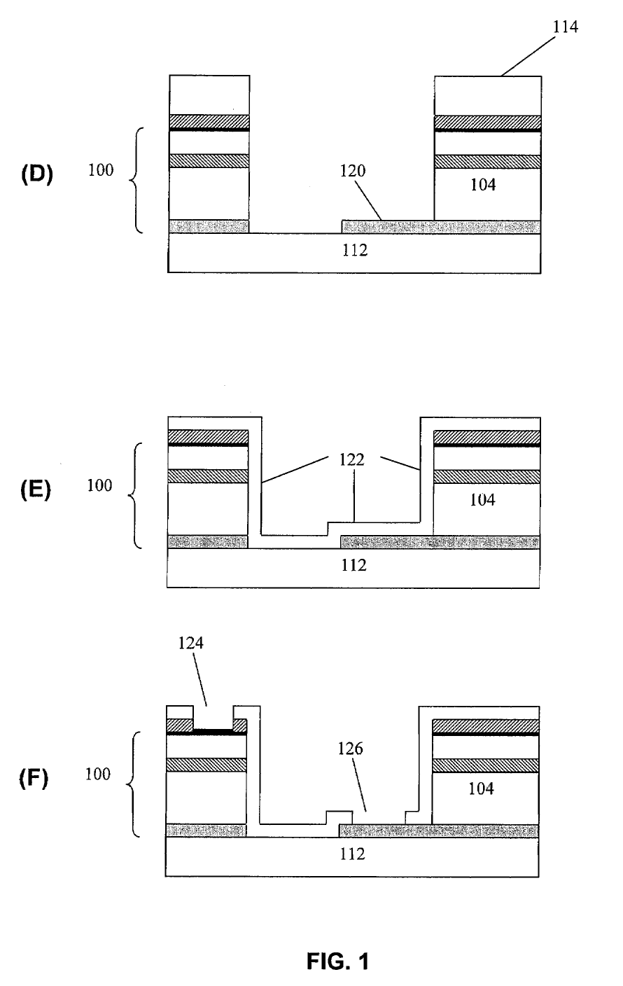

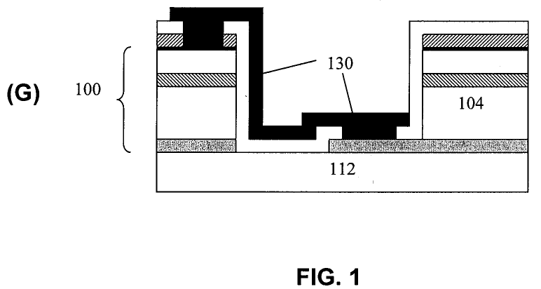

An example process flow for fabricating devices that incorporate a TCO layer according to the invention is illustrated in FIGS. 1A-F. It should be noted that the below drawings are not necessarily to scale, and relative dimensions of various layers and features will be specified in the descriptions where examples are appropriate. The drawings are intended for illumination rather than limitation. Moreover, the process flow described below finds particular usefulness in forming a thin film photovoltaic device. However, the TCO layer of the invention is not limited to this application, and those skilled in the art will understand how to implement the invention in other types of devices.

In the first step shown in FIG. 1A, the starting material is a stack 100 on a substrate 112 such as a 3 mm thick sheet of soda lime glass (SLG). In one embodiment, stack 100 includes a 0.1 μm layer 102 corresponding to the opaque metal electrode—typically molybdenum or MoSe₂—in contact with the glass substrate 112, a 2 μm semiconducting or absorbing layer 104, and a 1 μm layer 108 corresponding to the multi-layer TCO structure of the present invention on the top surface. In one example, the layer 108 comprises a ZnO layer about 4500 Å thick and an InO, SnO or ITO layer about 500 Å thick. Those skilled in the art will appreciate, however, that the etch selectivity between different layers, such as between the top dielectric layer and InO/SnO/ITO, in wet etch may determine the thickness of the InO/SnO/ITO material in layer 108 that will be needed to sufficiently protect the ZnO during processing, and so the invention is not limited to this example.

For this illustrated process flow, the semiconducting layer 104 is CIGS under a 0.07 μm buffer layer 106 of CdS, but any other appropriate semiconducting or absorbing material including micromorph, CIS, α:Si, μC:Si, CdTe, or stacks of multiple materials, could also be used, and the buffer layer need not be included.

As further shown in this example, an additional layer of material such as SiNₓ 110 can be deposited, by PEVCD for example, on the top of the stack to protect the TCO layer 108. Other protection layer materials are possible, such as SiO₂ BARC or BCB.

The first step in the process flow is to make an isolation cut through the stack 100 to the glass. According to an aspect of the invention, this is done with an etch process rather than laser or mechanical scribes, as will be described in more detail herein. For example, in this embodiment shown in FIG. 1B, a layer 114 of photoresist is applied to the module, using a spray, dip or roll-on process. The thickness may be 1-10 μm. 30 μm wide lines 116 are exposed in the photoresist using, for example, a mask (not shown) with a corresponding aperture suspended above or in contact with the substrate. The exposed photoresist is developed and removed.

In FIG. 1C, the resist is developed and isolation cuts 118 are etched to the glass using either a wet or dry etch process. In one example of a staged wet etch process according to the invention, a HCl or CH₃COOH solution can be used to etch through the TCO layer 108 and protect layer 110, then a H₂SO₄+HNO₃ process can be used to etch through the CIGS/CdS layer 104/106, then a H₃PO₄+CH₃COOH+HNO₃ (commonly called PAN etch) process can be used to etch through the Mo layer 102. It should be noted that the CIGS layer etch process is unique and novel in and of itself, and various example methods of performing this or alternative CIGS etch processes are described in more detail in co-pending application Ser. No. 11/395,080, the contents of which are incorporated herein by reference. Likewise, certain advantages can be obtained by using an etch process for the Mo layer 102 as described in more detail in co-pending application No. ______ (AMAT-11239).

It should be further noted that, in accordance with aspects of the multi-layer TCO structure of the invention, because ITO, InO and/or SnO is further provided in the TCO as a protective layer, it protects the ZnO film in the TCO layer from adverse effects during the etch processing described above, as well as subsequent processing described below. Moreover, based on the example materials, etch systems, etch processes and thicknesses provided above, those skilled in the art will understand how to implement alternative etch systems, etch processes, material layers and/or thicknesses, and so the invention is not limited to the above examples.

FIG. 1D illustrates a next step which begins a process of forming a conductive step or contact step according to one preferred embodiment of forming a photovoltaic device. In accordance with techniques described in more detail in co-pending application Ser. No. 11/394,721, the contents of which are incorporated herein by reference, a reflector or mirror is placed in close proximity to the top surface (e.g. 50 μm) and the illumination is incident from the under side of the glass substrate 112 at an angle. The light reflects from the mirror and exposes a region of photoresist adjacent to the already formed scribe 118. Therefore, this exposure is self-aligned to the existing scribe, and creates a step 120 with a width according to formulae described in the co-pending application.

Following exposure, development and removal of the photoresist region, an etch is performed to form the conductive step 120. This may be done with either a dry etch or wet etch, or a combination of both. As in the previous etch processes to form groove 118, the etch chemistry may be changed to selectively progress through each layer of the cell stack. In some embodiments, the etch is stopped when the bottom conductor is reached (molybdenum in the case of CIGS or ZnO in the case of α:Si or μC:Si). In other cases, the etch may be stopped in the semiconductor layer. For example, in α:Si or μC:Si the semiconductor is heavily doped near the bottom, and contact to this heavily doped region is acceptable.

In FIG. 1E, the photoresist is completely removed and a passivation layer 122 about 500 Å thick is deposited over the entire module (for example by chemical vapor deposition of SiO₂). Then, as shown in FIG. 1F, contact regions 124 and 126 are defined using photolithography and exposed, for example by wet etch in diluted HF solution, through the passivation layer 122 on areas of the TCO layer 108 adjacent to groove 118, and contact step 120, respectively.

Next as shown in FIG. 1G, metal layer comprised of Al is deposited by sputtering, for example. The metal is patterned using lithographic and etch techniques known in the art to form the metal contact 130 between cells. The final structure is shown in FIG. 1G.

Although the present invention has been particularly described with reference to the preferred embodiments thereof, it should be readily apparent to those of ordinary skill in the art that changes and modifications in the form and details may be made without departing from the spirit and scope of the invention. It is intended that the appended claims encompass such changes and modifications.

What is claimed is:

1. A thin film device comprising:
a transparent conducting oxide (TCO) structure including:
a first TCO material; and
a second different TCO material,
wherein the TCO structure has a greater proportion of the first TCO material than the second TCO material, and
wherein the second TCO material has a higher durability against chemical processing than the first TCO material.

2. A device according to claim 1 wherein the device comprises a photovoltaic device.

3. A device according to claim 1 wherein the device comprises a flat-panel display.

4. A device according to claim 2, wherein the TCO structure is included in a solar cell stack.

5. A device according to claim 2, wherein the TCO structure is included in a CIGS solar cell stack.

6. A device according to claim 2, wherein the TCO structure is included in a CdTe solar cell stack.

7. A device according to claim 2, wherein the TCO structure is included in a micromorph solar cell stack.

8. A device according to claim 1, wherein the first TCO material consists substantially of ZnO.

9. A device according to claim 1, wherein the second TCO material consists substantially of one of InO, SnO and ITO.

10. A device according to claim 8, wherein the second TCO material consists substantially of one of InO, SnO and ITO.

11. A device according to claim 1, wherein the proportion is about 9:1.

12. A device according to claim 10, wherein the proportion is about 9:1.

13. A processing method comprising:
forming a TCO structure comprised of at least two different TCO materials;
including the TCO structure in a thin film stack; and
using an etch process to completely etch through a portion of the thin film stack including the TCO structure,
wherein the forming step includes selecting the TCO materials such that the TCO structure is not degraded by the etch process.

14. A method according to claim 13, wherein the selecting step includes selecting a greater proportion of the first TCO material than the second TCO material, wherein the second TCO material has a higher durability against chemical processing than the first TCO material.

15. A method according to claim 14, wherein the proportion of the first TCO material to the second TCO material is about 9:1.

16. A method according to claim 14, wherein the first TCO material consists substantially of ZnO.

17. A method according to claim 14, wherein the second TCO material consists substantially of one of InO, SnO and ITO.

18. A method according to claim 16, wherein the second TCO material consists substantially of one of InO, SnO and ITO.
